(19) United States
(12) Patent Application Publication
(10) Pub. No.: US 2026/0182349 A1
(43) Pub. Date: Jun. 25, 2026

(54) INTERCONNECT STRUCTURE FORMATION USING GRADIENT DIELECTRIC

(71) Applicant: International Business Machines Corporation, Armonk, NY (US)

(72) Inventors: Kamal Rudra, Albany, NY (US); Ashim Dutta, Clifton Park, NY (US); Chih-Chao Yang, Glenmont, NY (US); Nilanka W. Sirikkathuge, Guilderland, NY (US)

(21) Appl. No.: 19/001,164

(22) Filed: Dec. 24, 2024

(51) Int. Cl. H01L 23/528; H01L 21/768; H01L 23/522

(52) U.S. Cl. CPC H10W 20/435; H10W 20/075; H10W 20/084; H10W 20/42

(57) ABSTRACT

A semiconductor device includes a first metallization level including a first dielectric layer and a first interconnect structure embedded in the first dielectric layer and a second metallization level including a second dielectric layer, a third dielectric layer, and a second interconnect structure, where the second interconnect structure includes a trench portion and a via portion. A dielectric constant of the second dielectric layer varies from a top surface of the second dielectric layer to a bottom surface of the second dielectric layer, and the via portion of the second interconnect structure extends through at least the second dielectric layer and contacts a top surface of the first interconnect structure.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments described herein provide techniques for forming an interconnect structure with a gradient dielectric layer.

In an illustrative embodiment, a semiconductor device includes a first metallization level including a first dielectric layer and a first interconnect structure embedded in the first dielectric layer and a second metallization level including a second dielectric layer, a third dielectric layer, and a second interconnect structure, where the second interconnect structure includes a trench portion and a via portion. A dielectric constant of the second dielectric layer varies from a top surface of the second dielectric layer to a bottom surface of the second dielectric layer, and the via portion of the second interconnect structure extends through at least the second dielectric layer and contacts a top surface of the first interconnect structure.

In another embodiment, a semiconductor device includes a first dielectric layer having a gradient dielectric constant that decreases from a top surface to a bottom surface of the first dielectric layer and a second dielectric layer, positioned above the first dielectric layer, including a uniform dielectric constant that is lower than the gradient dielectric constant at the top surface of the first dielectric layer. The semiconductor device further includes a first interconnect structure including a trench portion and a via portion, where the trench portion is embedded within the second dielectric layer, and where the via portion is positioned below the trench portion and extends through the first dielectric layer and contacts a top surface of a second interconnect structure.

In yet another embodiment, a method includes forming a first interconnect structure in a first dielectric layer, depositing one or more etch stop layers over the first dielectric layer and forming a second dielectric layer over the one or more etch stop layers, where a dielectric constant of the second dielectric layer varies from a top surface to a bottom surface. The method includes forming a third dielectric layer over the second dielectric layer, where the third dielectric layer includes a uniform dielectric constant that is lower than the dielectric constant of the second dielectric layer at its top surface. The method further includes forming a second interconnect structure using a dual damascene process, where the second interconnect structure comprises a trench portion formed in the third dielectric layer and a via portion that extends through at least the second dielectric layer and the one or more etch stop layers to contact the first interconnect structure.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure during an intermediate step of a method of fabricating an interconnect structure, according to an illustrative embodiment.

FIG. 2 depicts a cross-sectional view of the semiconductor structure following dielectric layer formation, according to an embodiment.

FIG. 3 depicts a cross-sectional view of the semiconductor structure following formation of etch stop layers and a hardmask (HM) layer, and patterning of the HM layer, according to an embodiment.

FIG. 4 depicts a cross-sectional view of the semiconductor structure following trench formation, according to an embodiment.

FIG. 5 depicts a cross-sectional view of the semiconductor structure following formation of an organic planarization layer (OPL), anti-reflective coating (ARC) layer, and a photoresist (PR) layer, and patterning of the PR layer, according to an embodiment.

FIG. 6 depicts a cross-sectional view of the semiconductor structure following an etching process for a via, according to an embodiment.

FIG. 7 depicts a cross-sectional view of the semiconductor structure following removal of the OPL, according to an embodiment.

FIG. 8 depicts a cross-sectional view of the semiconductor structure following partial removal of one of the etch stop layers, according to an embodiment.

FIG. 9 depicts a cross-sectional view of the semiconductor structure following formation of an interconnect structure and a planarization process, according to an embodiment.

FIG. 10 depicts a cross-sectional view of another semiconductor structure, according to an embodiment.

### DETAILED DESCRIPTION

Illustrative embodiments may be described herein in the context of illustrative methods for forming an interconnect structure with a gradient dielectric layer, along with illustrative apparatus, systems, and devices formed using such methods. However, it is to be understood that embodiments are not limited to the illustrative methods, apparatus, systems, and devices but instead are more broadly applicable to other suitable methods, apparatus, systems, and devices.

Semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. For example, semiconductor devices rely on a plurality of metallization layers or metal lines stacked on top of one another on the semiconductor substrate to provide electronic interconnections between integrated circuits on the substrate. A metallization layer may also be referred to as a BEOL metallization layer which could be disposed on a semiconductor material stack. Semiconductor contacts in a top layer in the semiconductor material stack are electrically connected to metal contacts and metal interconnects in a metallization layer disposed on the semiconductor material stack.

Generally, interconnects are structures that connect two or more circuit elements (such as transistors or power rails) together electrically. In addition to providing the electrical connection to the frontend devices (such as transistors), interconnects also go all the way back to the power delivery networks. Thus, interconnects and their surrounding support components are considered BEOL components. Lines and vias are important components of interconnect technology. Lines provide electrical connections within a single layer, and vias provide electrical connections between layers in a physical electronic circuit.

As technology continues to be scaled and transistors become smaller, increasingly tightly spaced interconnects are required to connect to them. Scaling interconnects pushes the boundaries of minimum widths, minimum spacings, and minimum pitches. However, these decreasing sizes and increasing densities introduce performance and reliability issues. In particular, critical dimensions refer to the sizes of electronic components that must be maintained to avoid unwanted impacts on the electrical properties of the device. Accordingly, the geometric properties of interconnect structures are limited not only by fabrication constraints but also by performance constraints.

Currently, there is a substantial risk of shorting between a via connecting one metallization level (e.g., Mₓ₊₁ level) to a first metal line of another metallization layer (e.g., Mₓ₊₁ level) and a second metal line of the Mₓ₊₁ level that is adjacent to the first metal line. For instance, conventional processes typically involve steps that cause flaring at the top of the via profile, which increases the likelihood of a shorting with an adjacent metal line, for example. The flaring at the top of the via profile is caused by erosion of material during one or more etching processes when forming the via.

In this context and elsewhere herein, the term “erosion” generally refers to the unintentional removal or alteration of material from a surface or structure resulting from one or more processes resulting in a deviation from the intended geometry or composition of that surface or structure. The removal or alteration of the material can be caused by various physical or chemical mechanisms, including but not limited to wet etching, dry etching, sputtering, and/or chemical reactions. Erosion can occur on the surface of a substrate, a deposited layer, a patterned feature, a mask layer, or other components of a semiconductor structure. In some examples, erosion can cause a reduction in material thickness, or an alteration of a feature's profile (e.g., sidewall angle changes and/or undercutting).

Because of these issues, interconnect structures often require greater spacing between metal lines to reduce the risk of shorting, leading to increased overall dimensions. Illustrative embodiments described herein can advantageously mitigate the risk of shorts between vias and adjacent metal lines by incorporating a dielectric layer with a gradient in its dielectric constant (k-value). For example, the dielectric layer can have a dielectric constant that varies from a higher k-value at the top surface to a lower k-value at the bottom surface. The gradient dielectric layer can help control via top erosion depth (d) and the tapered angle (θ) of the via, thereby preventing shorts that would otherwise occur due to via blow-out or via top flaring, for example. Accordingly, embodiments described herein can enable tighter spacing between metal lines without compromising reliability, which can effectively overcome the challenges with existing techniques.

Detailed embodiments of interconnect structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not intended to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

It will be understood that, although the terms first, second, etc., may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present disclosure.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

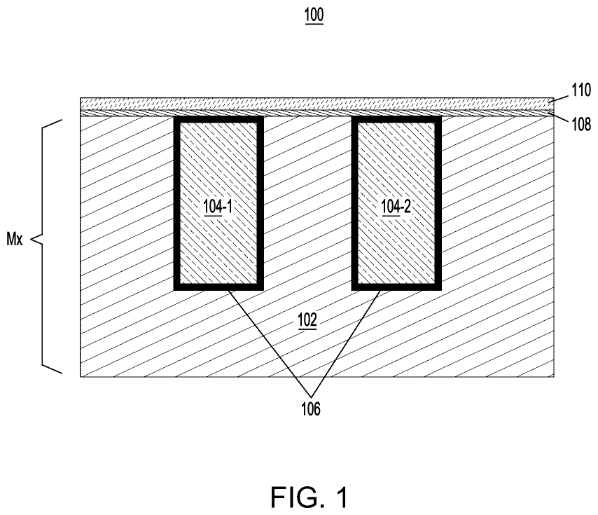

Referring now to the drawings, in which like numerals represent the same or similar elements, FIGS. 1-9 illustrate various processes for fabricating interconnects with a gradient dielectric layer. Note that the same reference numeral (100) denotes the semiconductor structure through the various intermediate fabrication stages illustrated in FIGS. 1-9. Note also that the interconnect structure described herein can also be considered to be a semiconductor device and/or an integrated circuit, or some part thereof. For the purpose of clarity, some fabrication steps leading up to the production of the interconnect structures as illustrated in FIGS. 1-9 are omitted. In other words, one or more well-known processing steps which are not illustrated but are well known to those of ordinary skill in the art have not been included in the figures. This is not intended to be interpreted as a limitation of any particular embodiment, or illustration, or scope of the claims.

FIG. 1 depicts a cross-sectional view of a semiconductor structure 100 following an intermediate fabrication stage. Specifically, the semiconductor structure 100 includes a first metallization layer Mₓ and an interlayer dielectric (ILD) layer 102. Metal lines 104-1 and 104-2 (collectively “metal lines 104”) surrounded by metallic liners 106 are formed in the ILD layer 102. A first etch stop layer 108 and a second etch stop layer 110 are formed above the ILD layer 102 and the metal lines 104, as shown.

In some embodiments, the semiconductor structure is formed on a substrate (not shown). For example, the substrate can include semiconductor materials such as silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material includes silicon. The substrate can include a bulk semiconductor substrate or a semiconductor-on-insulator (SOI) substrate. In an illustrative embodiment, the substrate may already have pre-built structures (not shown), such as FETs, transistors, diodes, resistors, capacitors, inductors, interconnects, electrically programmable fuses, and/or combinations thereof.

The ILD layer 102 may comprise, for example, silicon oxide (SiOₓ), silicon oxycarbide (SiOC), silicon oxycarbonitride (SiOCN), or some other dielectric. A process such as CVD, ALD, or PVD can be used to deposit the ILD layer 102. Subsequently, a planarization process such as a standard planarization process (e.g., a CMP process) can be carried out to planarize the upper surface of ILD layer 102.

In an illustrative embodiment, the metallic liners 106 can comprise a metal adhesion layer (e.g., TiN), and the metal lines 104 can be formed of any suitable conductive material, such as tungsten (W), aluminum (Al), copper (Cu), cobalt (Co), ruthenium (Ru), chromium (Cr), molybdenum (Mo), etc. The metal lines 104 can be formed, for example, using a suitable deposition technique such as CVD, PECVD, ALD, PVD, ALD, molecular beam deposition (MBD), pulsed laser deposition (PLD), liquid source misted chemical deposition (LSMCD), sputtering, and/or plating, followed by a planarization process (e.g., CMP).

The first etch stop layer 108 and the second etch stop layer 110 can include any suitable etch stop material, such as nitride materials and/or oxide materials. For example, in one embodiment, the first etch stop layer 108 may be formed of aluminum oxide (AlOx) or aluminum nitride (AlN), and the second etch stop layer 110 may be formed of silicon oxycarbide (SiCO). In other embodiments, a third etch stop layer (not shown) comprising AlOx or AlN can be deposited on top of the second etch stop layer 110. The third etch stop layer can advantageously provide improved control over the profile and chamfer angle during via formation, which can further improve reliability and protection against shorts, for example.

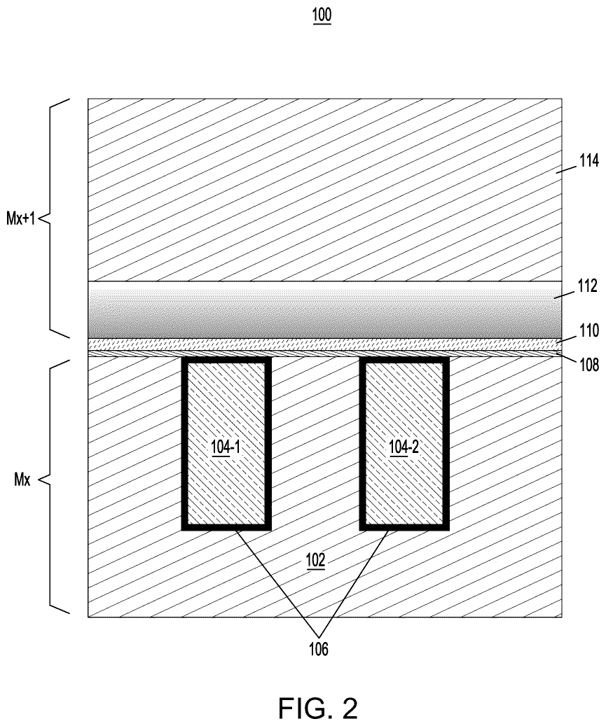

FIG. 2 depicts a cross-sectional view of the semiconductor structure 100 following formation of a second metallization layer Mₓ₊₁. Forming the second metallization layer Mₓ₊₁ includes first forming a gradient dielectric layer 112 on the second etch stop layer 110 followed by forming a dielectric layer 114 on the gradient dielectric layer 112.

In some embodiments, a dielectric constant of the gradient dielectric layer 112 varies from a first value (X) at the top surface to a second value (Y) at the bottom surface, where X>Y. such embodiments, the dielectric layer 114 can be formed on top of the gradient dielectric layer 112 and can comprise a material having a uniform dielectric constant substantially equal to Y. As a non-limiting example, if the dielectric constant at the top surface of the gradient dielectric layer 112 is equal to 4 (X=4), then the dielectric constant at the bottom surface of the gradient dielectric layer 112 and throughout the dielectric layer 114 can be equal to 3 (Y=3) or some other value that is less than 4.

In another embodiment, the dielectric constant of the gradient dielectric layer 112 varies from X at the top surface to a third value (Z) at the bottom surface, and the dielectric layer 114 can comprise a uniform dielectric constant that is equal to Y, where X>Y>Z. As a non-limiting example, the dielectric constant at the top surface of the gradient dielectric layer 112 can be equal to 4 (X=4), the dielectric constant at the bottom surface of the gradient dielectric layer 112 can be equal to 3 (Z=3), and the dielectric constant throughout the dielectric layer 114 can be equal to 3.5 (Y=3.5).

The gradient dielectric layer 112 can be formed by using various techniques, such as by varying chemistry parameters during the deposition process and/or depositing multiple layers to form a gradient of dielectric constant. For embodiments where the value of dielectric constant on the top surface of the gradient dielectric layer 112 is lower than the dielectric constant of the dielectric layer 114, the deposition of the gradient dielectric layer 112 can be performed in such a way that the interface between the gradient dielectric layer 112 and the dielectric layer 114 is protected from moisture and damage. The dielectric layer 114 may comprise, for example, SiOx, SiOC, SiOCN, and/or other dielectrics, and the gradient dielectric layer 112 may be formed of similar materials as the dielectric layer 114 or multiple layers of such materials.

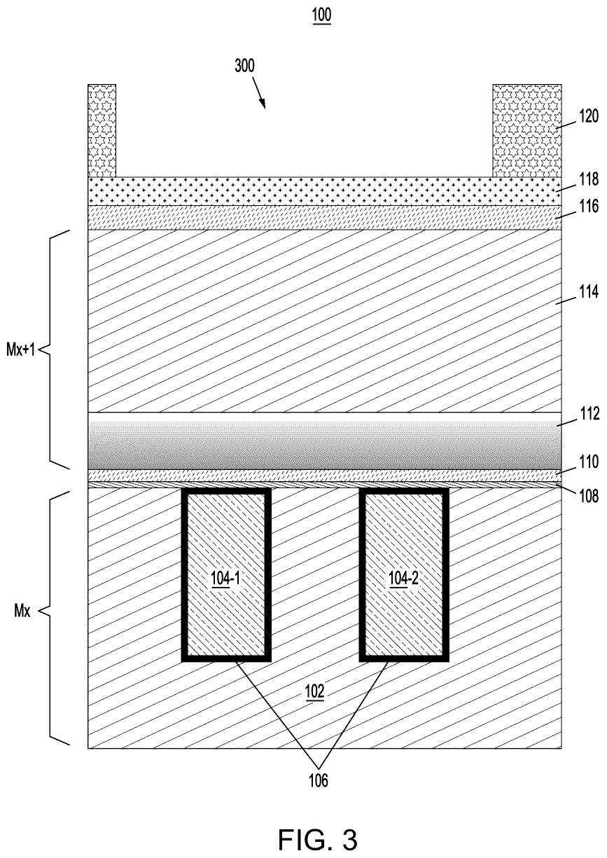

FIG. 3 depicts a cross-sectional view of the semiconductor structure following formation of etch stop layers 116 and 118 and an HM layer 120. The etch stop layer 116 is formed on the dielectric layer 114 and can comprise TiN, for example. The etch stop layer 118 is formed on the etch stop layer 116 and can comprise SiN, for example.

The HM layer 120 is deposited on the etch stop layer 118 using a suitable deposition technique such as PVD, ALD, CVD, etc. The HM layer 120 can be formed of a masking material, such as amorphous silicon or any other suitable masking material. An opening 300 is formed in the HM layer 120 using, for example, a dry etching process using RIE or IBE, a wet chemical etching process, or a combination of these etching processes.

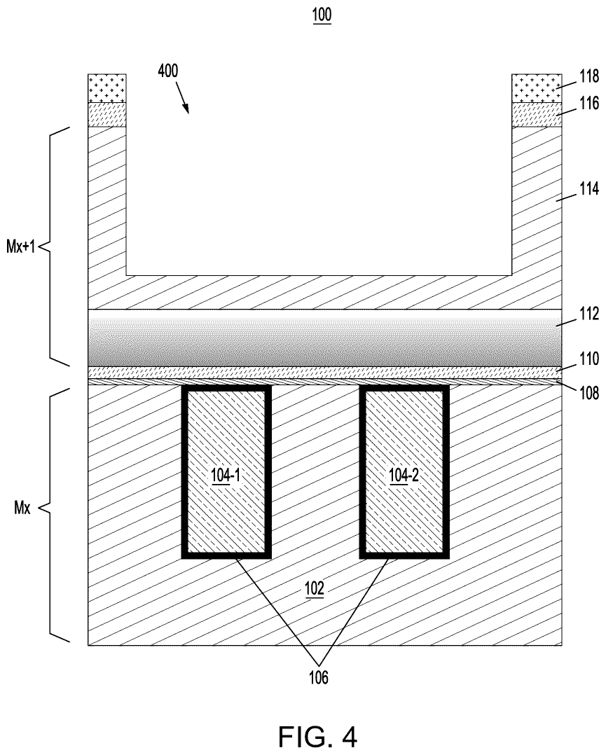

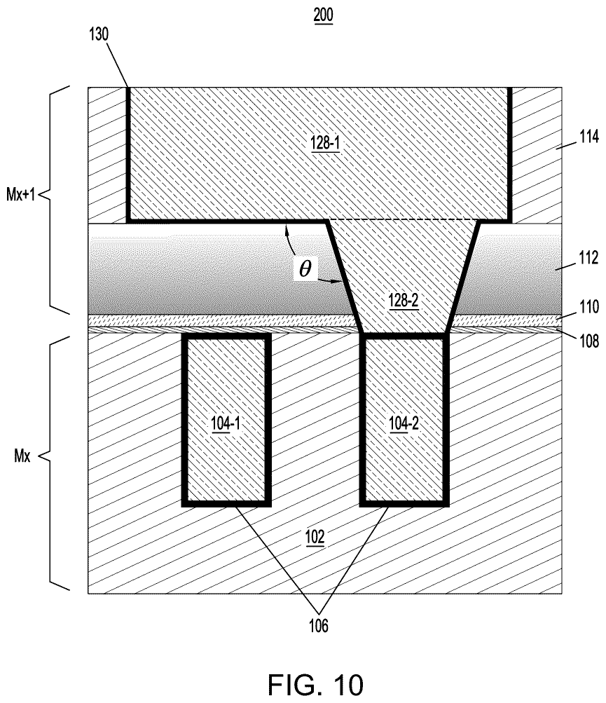

FIG. 4 depicts a cross-sectional view of the semiconductor structure following formation of a trench 400 in the dielectric layer 114. The trench 400 can be formed in the dielectric layer 114 using a dry etching process (e.g., RIE or IBE), a wet chemical etching process, or a combination of these etching processes to remove portions of the etch stop layers 116 and 118 and portions of the dielectric layer 114 that are exposed by the opening 300. In the FIG. 4 example, the trench 400 extends down into the dielectric layer 114 without exposing the top surface of the gradient dielectric layer 112. In other embodiments, the trench 400 can extend through the dielectric layer 114 to expose the top surface of the gradient dielectric layer 112, as discussed in more detail in conjunction with FIG. 10.

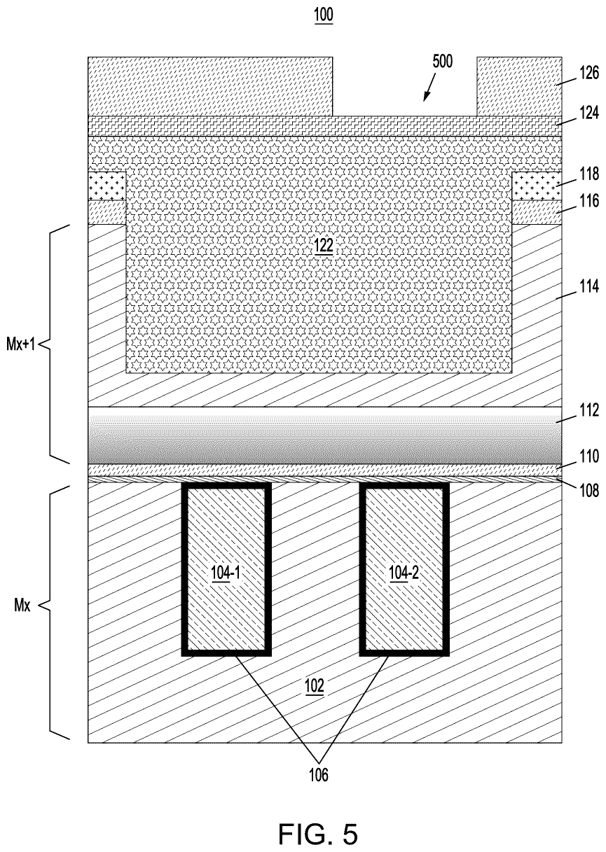

FIG. 5 depicts a cross-sectional view of the semiconductor structure following formation of an OPL 122, an ARC layer 124, and a PR layer 126. The OPL 122 can be deposited to fill in the trench 400 and the top surface of the semiconductor structure 100, as shown. The OPL 122 can be formed of an organic polymer such as carbon, hydrogen, and/or nitrogen, for example. In some embodiments, the ARC layer 124 comprises a silicon-based material such as silicon nitride, silicon oxide, silicon oxycarbide, etc. An opening 500 is formed in the PR layer 126, which can comprise a suitable light-sensitive polymer, for example.

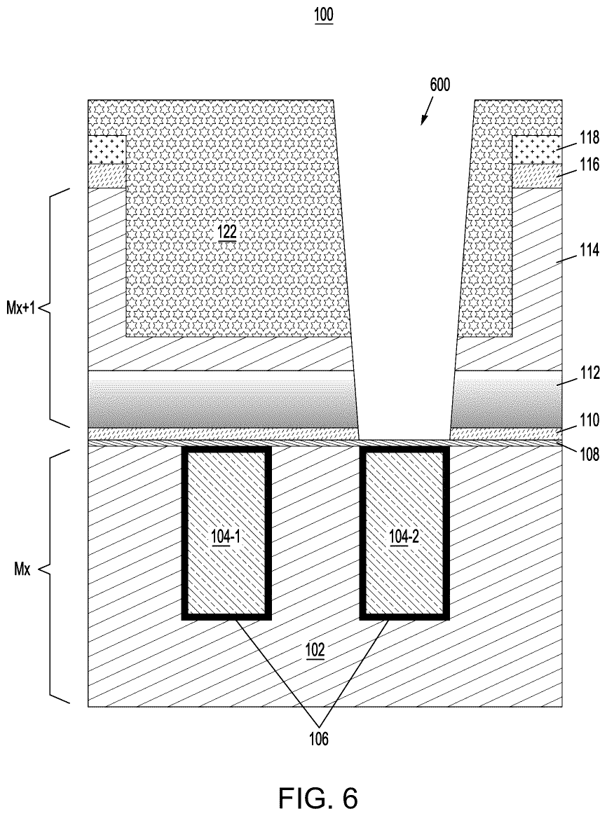

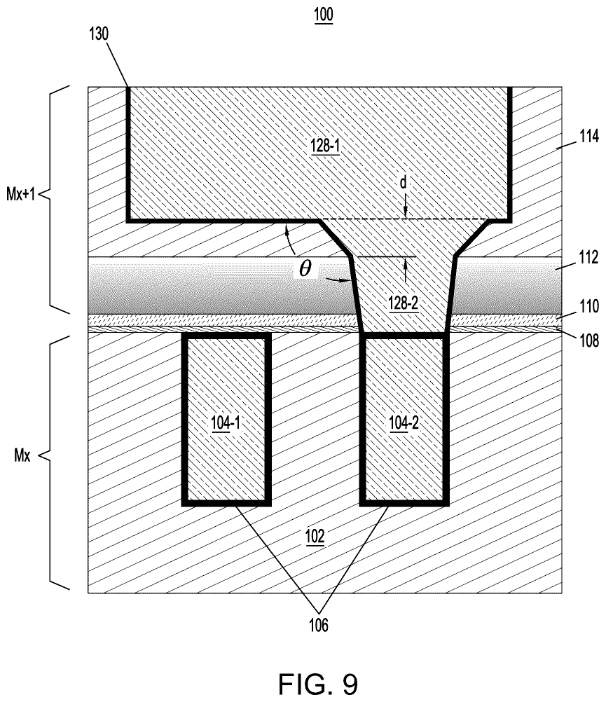

FIG. 6 depicts a cross-sectional view of the semiconductor structure following an etching process to form an opening 600. It is noted that the trench 400 and the opening 600 respectively correspond to trench portion 128-1 and via portion 128-2, collectively forming an interconnect structure 128, as described in more detail in conjunction with FIG. 9.

The etching process can include a dry etching process (e.g., RIE or IBE), a wet chemical etching process, or a combination of these etching processes to remove portions of the ARC layer 124, the OPL 122, the dielectric layer 114, the gradient dielectric layer 112, and the second etch stop layer 110 that are below the opening 500 to expose a top surface of the first etch stop layer 108 above the metal line 104-2. A planarization process (e.g., CMP) can be performed to remove the portion of the ARC layer 124 and the PR layer 126 that are above the OPL 122.

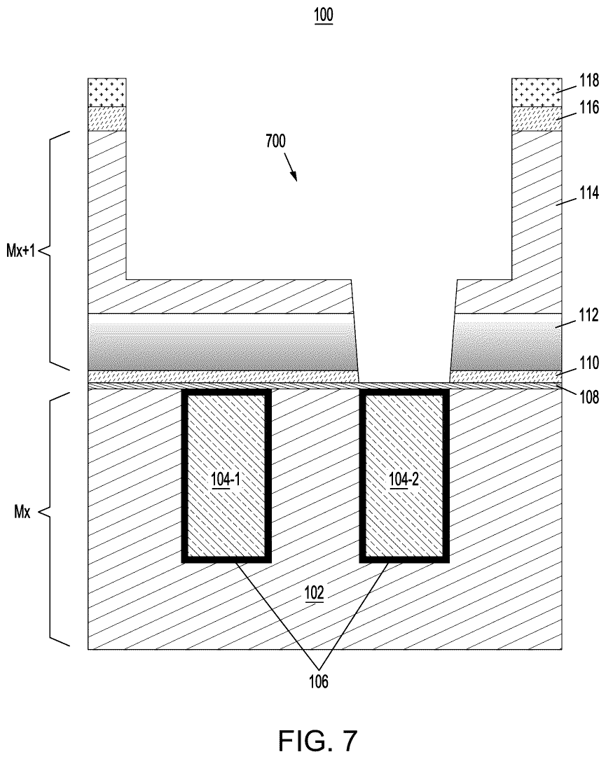

FIG. 7 depicts a cross-sectional view of the semiconductor structure following removal of the remaining portions of the OPL 122. For example, an ashing process can strip the remaining portions of the OPL 122 using, for example, oxygen plasma, nitrogen/hydrogen plasma or other carbon strip process, thereby forming opening 700. The portion of the opening 700 corresponding to the via portion 128-2 extends through the gradient dielectric layer 112, the dielectric layer 114, and the second etch stop layer 110.

In alternative embodiments, the opening 600 can be formed prior to forming the trench 400, and such embodiments can result in substantially the same semiconductor structure 100 as shown in FIG. 7.

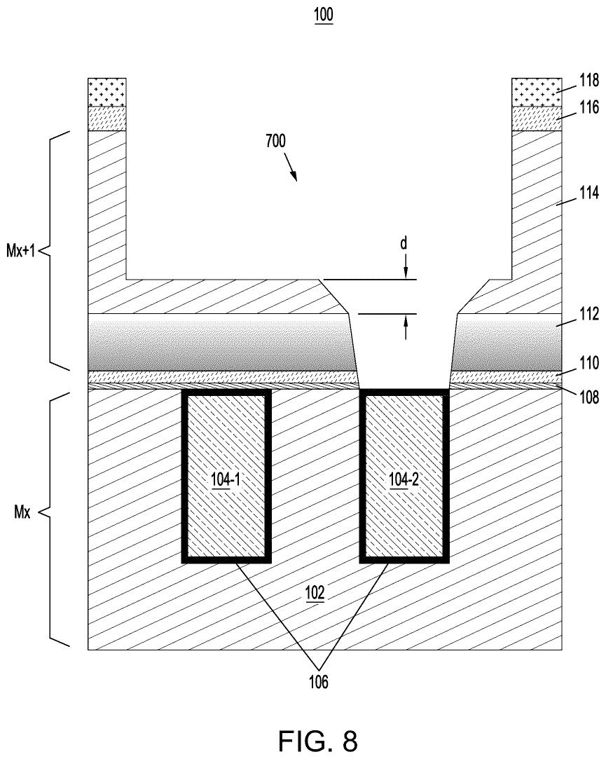

FIG. 8 depicts a cross-sectional view of the semiconductor structure following removal of a portion of the first etch stop layer 108 that is immediately above the metal line 104-2 using an etching process. The etching process can include a dry etching process (e.g., RIE or IBE), a wet chemical etching process, or a combination of these etching processes. During the etching process, portions of the dielectric layer 114 are eroded, thereby increasing the size of the opening 700. Specifically, the erosion causes the sidewalls of the dielectric layer 114 to flare outwards such that the sidewalls of the dielectric layer 114 have a different angle than the sidewalls of the gradient dielectric layer 112.

The depth (d) of the erosion occurring during the removal of the portion of the first etch stop layer 108 is limited/controlled by the existence of the gradient layer 112. Specifically, the thickness and composition of the gradient layer 112 directly affects the depth of the erosion. For example, the depth (d) is limited to the distance between the top surface of the dielectric layer 112 and the bottom surface of the trench 400 due to the varying dielectric constant of the gradient dielectric layer 112. This limits the amount of erosion in the portion of the opening 700 that is above the metal line 104-2.

FIG. 9 depicts a cross-sectional view of the semiconductor structure following formation of an interconnect structure 128 and a planarization process. A metallic liner 130 is formed on the surfaces exposed by the opening 700. The metallic liner can be formed using similar techniques and materials as metallic liners 106, for example. A conductive metal can then be deposited in the opening 700 using a suitable deposition process such as ALD, PVD, CVD or electroplating to form the interconnect structure 128. The conductive metal can comprise a similar material as the metal lines 104, for example. Subsequently, a planarization process (e.g., a CMP process) can be carried out to planarize the upper surface of the semiconductor structure 100. In the example shown in FIG. 9, the sidewalls of the via portion 128-2 adjacent to the gradient dielectric layer 112 are tapered at an angle (θ), and the sidewalls of the via portion 128-2 adjacent to the dielectric layer 114 are tapered at a different angle. In one embodiment, θ is preferably between 90 and 105 degrees.

It is to be appreciated that the gradient dielectric layer 112 provides enhanced control over the profile of the via portion 128-2 of the interconnect structure 128, which can reduce the likelihood of shorts between the via portion 128-1 and adjacent metal lines (e.g., metal line 104-1). In at least some embodiments, the gradient dielectric layer 112 can additionally improve protection against time-dependent dielectric breakdown (TDDB) as at least a portion of the gradient dielectric layer 112 can have a higher dielectric constant value than a typical dielectric layer, which generally has a single uniform dielectric constant. Accordingly, the use of the gradient dielectric layer 112 can improve scalability and reliability compared to techniques that use a dielectric layer having a single uniform dielectric constant.

FIG. 10 depicts a cross-sectional view of a semiconductor structure 200. The semiconductor structure 200 can be formed using similar techniques and materials as described for the semiconductor structure 100 shown in FIG. 9, except the trench portion 128-1 of the semiconductor structure 200 extends down to a top surface of the gradient dielectric layer 112. Such embodiments can reduce or eliminate any erosion during removal of the portion of the first etch stop layer 108 above the metal line 104-2. Accordingly, sidewalls of via portion 128-2 between the top surface of the second etch stop layer 110 and the bottom surface of the trench portion 128-1 are tapered at an angle (θ).

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to, CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In an illustrative embodiment, a semiconductor device includes a first metallization level including a first dielectric layer and a first interconnect structure embedded in the first dielectric layer and a second metallization level including a second dielectric layer, a third dielectric layer, and a second interconnect structure, where the second interconnect structure includes a trench portion and a via portion. A dielectric constant of the second dielectric layer varies from a top surface of the second dielectric layer to a bottom surface of the second dielectric layer, and the via portion of the second interconnect structure extends through at least the second dielectric layer and contacts a top surface of the first interconnect structure.

In embodiments, the dielectric constant of the second dielectric layer may decrease from the top surface to the bottom surface.

In embodiments, the third dielectric layer may be positioned above the second dielectric layer.

In embodiments, the third dielectric layer may have a uniform dielectric constant that is lower than the dielectric constant at the top surface of the second dielectric layer.

In embodiments, at least a first portion of a sidewall of the via portion of the second interconnect structure may be tapered at a first angle between 90 and 105 degrees, and at least a second portion of the sidewall of the via portion of the second interconnect structure is tapered at a second, different angle.

In embodiments, the semiconductor structure may further include a metallic liner positioned on bottom and side surfaces of the second interconnect structure.

In embodiments, the trench portion of the second interconnect structure may extend into a portion of the third dielectric layer.

In embodiments, the trench portion of the second interconnect structure may extend through the third dielectric layer and contacts a top surface of the second dielectric layer.

In embodiments, the dielectric constant at the bottom surface of the second dielectric layer may be higher than the dielectric constant of the third dielectric layer.

In embodiments, the dielectric constant at the bottom surface of the second dielectric layer may be lower than the dielectric constant of the third dielectric layer.

In embodiments, the dielectric constant of the second dielectric layer may decrease from a first value at the top surface to a second value at the bottom surface.

In embodiments, the third dielectric layer may include a uniform dielectric constant corresponding to a third value, where the first value is greater than the second value, and the second value is greater than the third value.

In embodiments, the semiconductor structure may further include one or more etch stop layers, where the one or more etch stop layers include a first etch stop layer including aluminum oxide or aluminum nitride and a second etch stop layer including silicon oxycarbide.

In embodiments, the one or more etch stop layers may include a third etch stop layer comprising aluminum oxide or aluminum nitride, wherein the second etch stop layer is positioned between the first etch stop layer and the third etch stop layer.

In another embodiment, a semiconductor device includes a first dielectric layer having a gradient dielectric constant that decreases from a top surface to a bottom surface of the first dielectric layer and a second dielectric layer, positioned above the first dielectric layer, including a uniform dielectric constant that is lower than the gradient dielectric constant at the top surface of the first dielectric layer. The semiconductor device further includes a first interconnect structure including a trench portion and a via portion, where the trench portion is embedded within the second dielectric layer, and where the via portion is positioned below the trench portion and extends through the first dielectric layer and contacts a top surface of a second interconnect structure.

In embodiments, at least a first portion of a sidewall of the via portion of the second interconnect structure may be tapered at a first angle between 90 and 105 degrees, and at least a second portion of the sidewall of the via portion of the second interconnect structure may be tapered at a second angle that is different than the first angle.

In embodiments, the semiconductor device may include one or more etch stop layers positioned below the first dielectric layer, and a metallic liner positioned on bottom and side surfaces of the first interconnect structure.

In yet another embodiment, a method includes forming a first interconnect structure in a first dielectric layer, depositing one or more etch stop layers over the first dielectric layer and forming a second dielectric layer over the one or more etch stop layers, where a dielectric constant of the second dielectric layer varies from a top surface to a bottom surface. The method includes forming a third dielectric layer over the second dielectric layer, where the third dielectric layer includes a uniform dielectric constant that is lower than the dielectric constant of the second dielectric layer at its top surface. The method further includes forming a second interconnect structure using a dual damascene process, where the second interconnect structure comprises a trench portion formed in the third dielectric layer and a via portion that extends through at least the second dielectric layer and the one or more etch stop layers to contact the first interconnect structure.

In embodiments, forming the second dielectric layer may include adjusting one or more deposition parameters to decrease the dielectric constant from the top surface to the bottom surface of the second dielectric layer.

In embodiments, forming the via portion may include performing an etching process to remove a portion of a bottom etch stop layer of the one or more etch stop layers above the first interconnect structure, where an amount of material removed by the etching process is constrained at least in part by a difference between the dielectric constant at the top surface and the bottom surface of the second dielectric layer.

In embodiments, wherein at least a portion of a sidewall of the via portion of the second interconnect structure is tapered with an angle between 90 and 105 degrees based at least in part on a result of the etching process.

Conventional techniques for designing and fabricating a dual damascene interconnect structure are difficult to scale due to the risk of shorts. Without in any way limiting the scope, interpretation, or application of the claims appearing below, a technical effect of one or more of the example embodiments disclosed herein is to reduce the risk of shorts by incorporating a gradient dielectric layer that controls the erosion depth and tapered angle of the via. The gradient dielectric layer effectively prevents via top flaring and reduces the risk of shorts due to via blowout, for example. Such techniques effectively improve reliability and scalability of dual damascene interconnect structures, particularly as semiconductor technology advances towards 2 nm nodes and beyond.

In the description above, various materials, dimensions, and processing parameters for different elements are provided. Unless otherwise noted, such materials are given by way of example only, and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first metallization level comprising a first dielectric layer and a first interconnect structure embedded in the first dielectric layer; and
a second metallization level comprising a second dielectric layer, a third dielectric layer, and a second interconnect structure, wherein the second interconnect structure comprises a trench portion and a via portion;
wherein a dielectric constant of the second dielectric layer varies from a top surface of the second dielectric layer to a bottom surface of the second dielectric layer, and wherein the via portion of the second interconnect structure extends through at least the second dielectric layer and contacts a top surface of the first interconnect structure.

2. The semiconductor structure of claim 1, wherein the dielectric constant of the second dielectric layer decreases from the top surface to the bottom surface.

3. The semiconductor structure of claim 1, wherein the third dielectric layer is positioned above the second dielectric layer.

4. The semiconductor structure of claim 3, wherein the third dielectric layer has a uniform dielectric constant that is lower than the dielectric constant at the top surface of the second dielectric layer.

5. The semiconductor structure of claim 1, wherein at least a first portion of a sidewall of the via portion of the second interconnect structure is tapered at a first angle between 90 and 105 degrees, and wherein at least a second portion of the sidewall of the via portion of the second interconnect structure is tapered at a second, different angle.

6. The semiconductor structure of claim 1, further comprising:
a metallic liner positioned on bottom and side surfaces of the second interconnect structure.

7. The semiconductor structure of claim 1, wherein the trench portion of the second interconnect structure extends into a portion of the third dielectric layer.

8. The semiconductor structure of claim 1, wherein the trench portion of the second interconnect structure extends through the third dielectric layer and contacts a top surface of the second dielectric layer.

9. The semiconductor structure of claim 1, wherein the dielectric constant at the bottom surface of the second dielectric layer is higher than the dielectric constant of the third dielectric layer.

10. The semiconductor structure of claim 1, wherein the dielectric constant at the bottom surface of the second dielectric layer is lower than the dielectric constant of the third dielectric layer.

11. The semiconductor structure of claim 1, wherein:
the dielectric constant of the second dielectric layer decreases from a first value at the top surface to a second value at the bottom surface; and
the third dielectric layer comprises a uniform dielectric constant corresponding to a third value, wherein the first value is greater than the second value, and the second value is greater than the third value.

12. The semiconductor structure of claim 1, further comprising:
one or more etch stop layers, wherein the one or more etch stop layers comprise a first etch stop layer comprising aluminum oxide or aluminum nitride and a second etch stop layer comprising silicon oxycarbide.

13. The semiconductor structure of claim 12, wherein the one or more etch stop layers comprise a third etch stop layer comprising aluminum oxide or aluminum nitride, wherein the second etch stop layer is positioned between the first etch stop layer and the third etch stop layer.

14. A semiconductor device, comprising:
a first dielectric layer having a gradient dielectric constant that decreases from a top surface to a bottom surface of the first dielectric layer;
a second dielectric layer, positioned above the first dielectric layer, comprising a uniform dielectric constant that is lower than the gradient dielectric constant at the top surface of the first dielectric layer; and
a first interconnect structure comprising a trench portion and a via portion, wherein the trench portion is embedded within the second dielectric layer, and wherein the via portion is positioned below the trench portion and extends through the first dielectric layer and contacts a top surface of a second interconnect structure.

15. The semiconductor device of claim 14, wherein at least a first portion of a sidewall of the via portion of the second interconnect structure is tapered at a first angle between 90 and 105 degrees, and wherein at least a second portion of the sidewall of the via portion of the second interconnect structure is tapered at a second, different angle.

16. The semiconductor device of claim 14, further comprising:
one or more etch stop layers positioned below the first dielectric layer; and
a metallic liner positioned on bottom and side surfaces of the first interconnect structure.

17. A method comprising:
forming a first interconnect structure in a first dielectric layer;
depositing one or more etch stop layers over the first dielectric layer;
forming a second dielectric layer over the one or more etch stop layers, wherein a dielectric constant of the second dielectric layer varies from a top surface to a bottom surface;
forming a third dielectric layer over the second dielectric layer, wherein the third dielectric layer comprises a uniform dielectric constant that is lower than the dielectric constant of the second dielectric layer at its top surface; and
forming a second interconnect structure using a dual damascene process, wherein the second interconnect structure comprises a trench portion formed in the third dielectric layer and a via portion that extends through at least the second dielectric layer and the one or more etch stop layers to contact the first interconnect structure.

18. The method of claim 17, wherein forming the second dielectric layer comprises:
adjusting one or more deposition parameters to decrease the dielectric constant from the top surface to the bottom surface of the second dielectric layer.

19. The method of claim 17, wherein forming the via portion comprises:
performing an etching process to remove a portion of a bottom etch stop layer of the one or more etch stop layers above the first interconnect structure, wherein an amount of material removed by the etching process is constrained at least in part by a difference between the dielectric constant at the top surface and the bottom surface of the second dielectric layer.

20. The method of claim 19, wherein at least a portion of a sidewall of the via portion of the second interconnect structure is tapered with an angle between 90 and 105 degrees based at least in part on a result of the etching process.
